(19) United States
(12) Patent Application Publication
(10) Pub. No.: US 2014/0063742 A1
(43) Pub. Date: Mar. 6, 2014

(54) Thermally Enhanced Electronic Component Packages with Through Mold Vias

(71) Applicants: Burton Jesse Carpenter, JR., Austin, TX (US); Nhat Dinh Vo, Austin, TX (US)

(72) Inventors: Burton Jesse Carpenter, JR., Austin, TX (US); Nhat Dinh Vo, Austin, TX (US)

(73) Assignee: FREESCALE SEMICONDUCTOR, INC., Austin, TX (US)

(21) Appl. No.: 13/596,802

(22) Filed: Aug. 28, 2012

(51) Int. Cl. H05K 7/20; H01K 3/10

(52) U.S. Cl. 361/705; 29/852

(57) ABSTRACT

Systems and methods for thermally enhanced electronic component packaging with through mold vias are described. In some embodiments, a method may include forming one or more vias through an encapsulant with a laser, each of the one or more vias having one end proximal a top surface of an electronic component covered by the encapsulant and another end proximal an outer surface of the encapsulant. The method may also include inserting a thermally conductive material into the one or more vias, providing a heat spreader over the outer surface of the encapsulant, the heat spreader thermally coupled to the thermally conductive material, and reflowing the thermally conductive material.

### FIELD

This disclosure relates generally to electronic component packages, and more specifically, to thermally enhanced electronic component packages with through mold vias.

### BACKGROUND

Electronic component packaging is the stage of electronic device manufacturing or fabrication in which an electronic component (e.g., an integrated circuit, etc.) is encased or encapsulated to prevent physical damage and/or corrosion to the component, and to support the component's electrical contacts. Most electronic devices typically contain one or more packaged circuits or components that are mounted on a Printed Circuit Board (PCB). Originally, these packages were fitted with discrete wire leads that were designed to be inserted into corresponding holes (or into a socket) on the PCB using so-called “through-hole” technologies. Since the 1980s, however, the use of Surface-Mount Technologies (SMT) has become widespread. An example of SMT is the Ball Grid Array (BGA) packaging, which allows complex components such as microprocessors to have a very large number (e.g., hundreds) of interconnection pins.

### BRIEF DESCRIPTION OF THE DRAWINGS

The present invention(s) is/are illustrated by way of example and is/are not limited by the accompanying figures, in which like references indicate similar elements. Elements in the figures are illustrated for simplicity and clarity and have not necessarily been drawn to scale.

FIG. 1 is a block diagram of a Printed Circuit Board (PCB) of a device having one or more electronic components enclosed within a thermally enhanced package with through mold vias according to some embodiments.

FIG. 2 is a cross-sectional diagram of an electronic component enclosed within a thermally enhanced package with through mold vias according to some embodiments.

FIG. 3 is a top view of an electronic component enclosed within a thermally enhanced package with through mold vias according to some embodiments.

FIG. 4 is a flowchart of a method of manufacturing a thermally enhanced electronic component package with through mold vias according to some embodiments.

FIGS. 5-11 are cross-section diagrams illustrating a method of manufacturing a thermally enhanced electronic component package with through mold vias according to some embodiments.

FIGS. 12 and 13 are cross-sectional diagrams illustrating designs of thermally enhanced electronic component packages with through mold vias according to some embodiments.

FIGS. 14-16 are top view diagrams illustrating designs of thermally enhanced electronic component packages with through mold vias according to some embodiments.

### DETAILED DESCRIPTION

Embodiments disclosed herein are directed to thermally enhanced electronic component packages and methods for manufacturing the same. In some implementations, a thermally enhanced electronic component package may be particularly well suited for encasing microprocessors, microcontrollers, etc. that are present in one or more electronic devices. It should be understood, however, that the apparatuses and techniques described below make specific reference to microprocessors, microcontrollers, etc. to merely to illustrate certain types of electronic circuits. The same or similar thermally enhanced packages may also be used to support any other type of circuits or other electronic components used in any type of device.

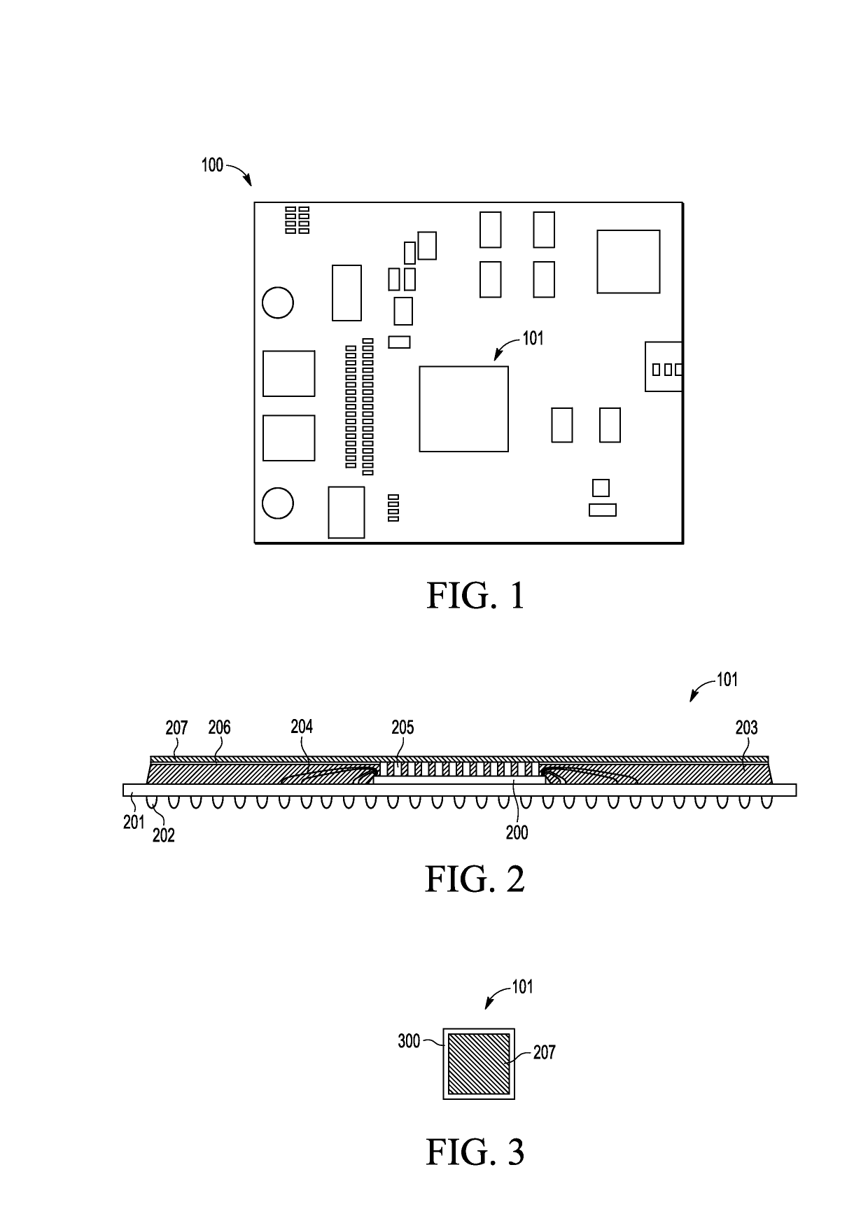

Turning to FIG. 1, a block diagram of a Printed Circuit Board (PCB) 100 of a device having one or more electronic components enclosed within thermally enhanced package 101 is depicted. In various embodiments, such a device may be, for example, a consumer appliance or information technology (IT) product (e.g., a computer, a tablet, a mobile phone, a television, a camera, a sound system, a router, a switch, etc.), a medical device or laboratory instrument (e.g., a imaging, diagnostic, or therapeutic equipment, etc.), a transportation vehicle (an automobile, a bus, a train, watercraft, aircraft, etc.), military or industrial equipment, or any other device having one or more electronic parts. In various implementations, PCB 100 may include a plurality of other elements in addition to electronic component package 101. Also, in some cases, electronic component package 101 may be mounted onto PCB 100 using a surface mount technology (e.g., Ball Grid Array (BGA) packaging) or the like.

Electronic component(s) within package 101 may include a semiconductor circuit, an integrated circuit, or any other type of circuit. For example, the electronic component(s) may include an Application Specific Integrated Circuit (ASIC), a System-on-Chip (SoC), a Digital Signal Processors (DSP), a Field-Programmable Gate Arrays (FPGA), a processor, a microprocessor, a controller, a microcontroller (MCU), or the like. Additionally or alternatively, the electronic component(s) may include a tangible memory apparatus including, but not limited to, a Static Random Access Memory (SRAM), a Magnetoresistive RAM (MRAM), a Nonvolatile RAM (NVRAM, such as “flash” memory), and/or a Dynamic RAM (DRAM) such as synchronous DRAM (SDRAM), a double data rate (e.g., DDR, DDR2, DDR3, etc.) SDRAM, a read only memory (ROM), an erasable ROM (EROM), an erasable programmable ROM (EPROM), an electrically erasable programmable ROM (EEPROM), etc. Additionally or alternatively, the electronic component(s) may include one or more analog circuits (e.g., analog to digital converters (ADC), digital to analog converters (DAC), Phased Locked Loop (PLL), etc.), capacitors, inductors, etc. Additionally or alternatively, the electronic component(s) may include one or more Micro-electromechanical Systems (MEMS), Nano-electromechanical Systems (NEMS), or the like. As such, the electronic component(s) within package 101 may include a number of different portions, areas, or regions (e.g., multiple processing cores, cache memories, internal bus(es), timing units, controllers, analog sections, mechanical sections, etc.), each having different thermal and/or heat dissipation characteristics.

In various embodiments, the electronic component(s) may be encased or otherwise disposed within package 101, and package 101 may have been thermally enhanced, at least in part, due to the presence of one or more through mold vias. In some cases, these through mold vias may create one or more thermal pathways from the top surface of the electronic component(s) (e.g., a semiconductor die) to the outer surface of package 101.

To illustrate the foregoing, FIG. 2 shows a cross-sectional diagram of semiconductor die 200 (i.e., a non-limiting example of an electronic component) enclosed within thermally enhanced package 101 according to some embodiments. As illustrated, semiconductor die 200 includes one or more electrical, electronic, or electro-mechanical circuits fabricated thereon, and it is coupled to substrate 201. Wirebonds 204, typically made of aluminum, copper, gold, or the like, are coupled to semiconductor die 200 and substrate 201. Together with solder balls or spheres 202 that are located under substrate 201, wirebonds 204 provide input and output electrical connections to semiconductor die 200. Encapsulant 203 (e.g., a mold compound, epoxy material, or any other material suitable for component encapsulation) encases semiconductor die 200 as well as wirebonds 204. One or more vias filled with thermally conductive material (e.g., a solder alloy, copper, etc.)—referred to as “filled vias” 205—are formed (e.g., by laser drilling, mechanical process(es), chemical etching, etc.) in encapsulant 203. As illustrated here, each of filled vias 205 may have one end proximal the top surface of semiconductor die 200 and another end proximal the outer surface of encapsulant 203. As such, the thermally conductive material within filled vias 205 may be thermally coupled to heat spreader 207 (e.g., a layer of copper or the like). In some cases, filled vias 205 may be metallurgically joined to heat spreader 207. Moreover, heat spreader 207 may be attached to encapsulant 203 through an adhesive bonding layer or the like; rather than being “molded in” to encapsulant 203.

In various implementations, there may be ˜0.3 mm to ˜1 mm of encapsulant 203 —material between the top surface of semiconductor die 200 and heat spreader 207, which may be ˜0.1 mm to ˜0.5 mm thick. Meanwhile, a suitable range of diameters for each of filled vias 205 may be ˜0.050 mm to ˜0.250 mm.

Encapsulant 203 generally has low thermal conductivity compared to metals. As such, the thermally conductive material deposited or otherwise inserted into filled vias 205 may improve the heat dissipation characteristics of package 101 by providing vertical, thermally conductive pathways from semiconductor die 200 directly to heat spreader 207—which in some cases may be sufficiently thick to reduce or eliminate the need for a plating layer of Thermal Interface Material (TIM) (e.g., metal) attached to a surface of semiconductor die 200. In some embodiments, a thermally conductive but electrically non-conductive material may be used to fill filled vias 205 to prevent undesirable electrical interactions. Additionally or alternatively, filled vias 205 may provide an electrical ground (GND) connection to semiconductor die 200. In some implementations, filled vias 205 may be provided across the entire surface of semiconductor die 200 or only selected portions thereof.

FIG. 3 is a top view of thermally enhanced electronic component package 101 according to some embodiments. As illustrated, in some cases, heat spreader 207 may occupy approximately and/or substantially the entire top surface area of the electronic component (e.g., semiconductor die 200) within perimeter 300, thus providing a larger heat exchange element. Here it is noted that the example shown in FIG. 3 is in contrast with conventional semiconductor packages, where a heat spreader does not extend to the perimeter of an electronic component because it is “molded into” the encapsulant material. In some cases, heat spreader 207 may be approximately coextensive with substrate 201 and/or it may have an exposed area that is larger than the top surface area of semiconductor die 200.

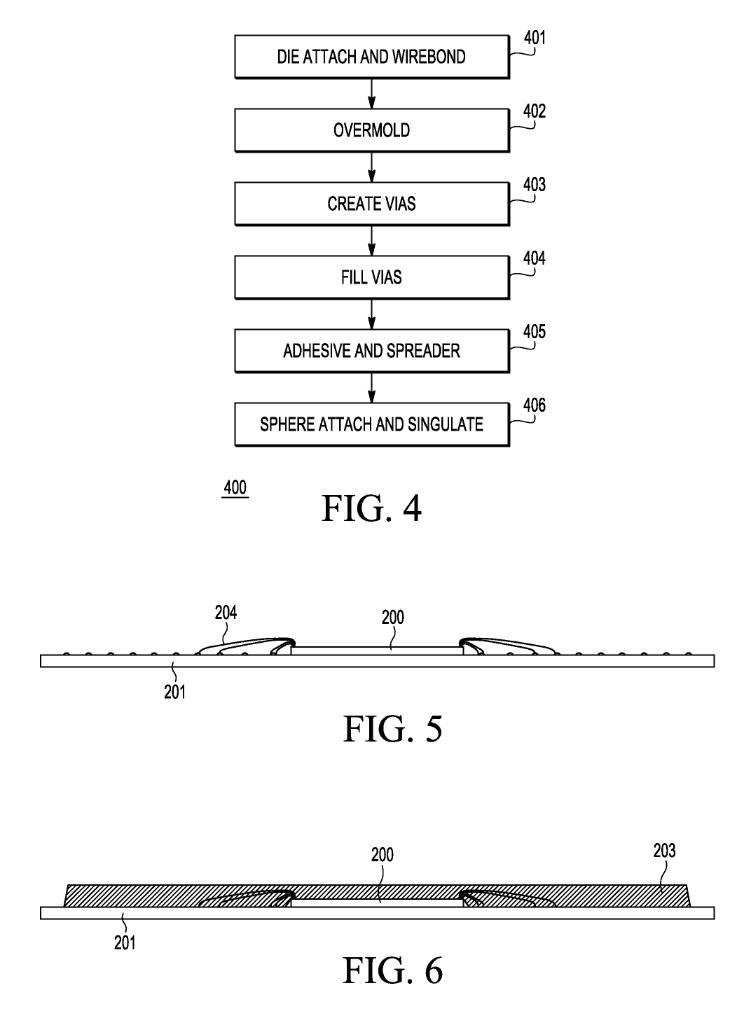

FIG. 4 is a flowchart of method 400 of manufacturing a thermally enhanced electronic component package with through mold vias according to some embodiments, and FIGS. 5-11 are cross-section diagrams illustrating method 400. Generally speaking, a set of two or more components may be attached to a substrate, after which they may undergo wirebonding and overmolding processes that result in a strip or set of packaged components. Each resulting package may then be singulated—i.e., sliced away from other packages and into individual parts.

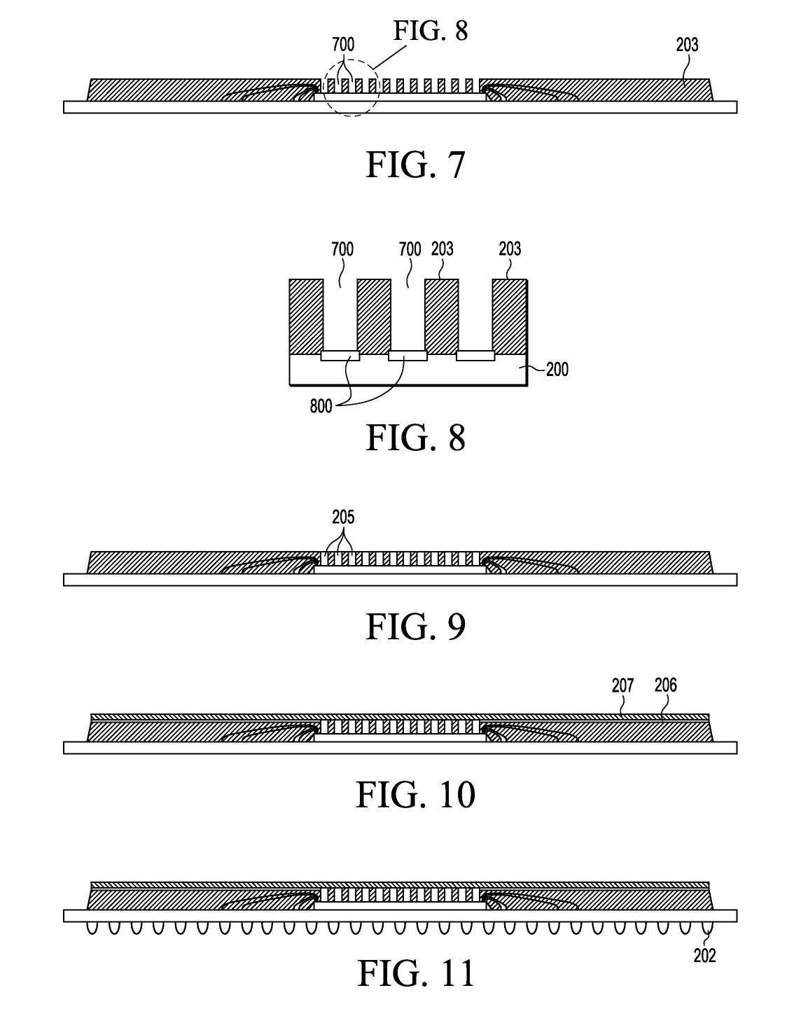

At block 401, method 400 includes attaching semiconductor die 200 to substrate 201 and forming wirebonds 204 as shown in FIG. 5. At block 402, method 400 includes depositing or otherwise overlaying encapsulant 203 over semiconductor die 200 (or other type of electronic component), as shown in FIG. 6. It should be noted that, at this stage, heat spreader 207 has not yet been used and thermally conductive pathways have yet to be provided. At block 403, method 400 includes drilling vias 700 through encapsulant 203, as shown in FIG. 7. For example, vias 700 may be drilled with a laser, mechanically, or through a photoresist/chemical etching process. In some embodiments, one or more stop pads 800 may be used to prevent drilling operation(s) from damaging semiconductor die 200, as shown in FIG. 8. For example, in cases where vias 700 are drilled with a laser, stop pads 800 may be metal pads or the like. In other cases where vias 700 are fabricated using a photoresist process, stop pads 800 may be etch-stop pads or the like. In some embodiments, stop pads 800 may be deposited in one or more areas of the top surface of semiconductor die 200 prior to the operations of block 402. For instance, in some cases, a stop layer may be deposited or overlaid upon the entire the top surface of semiconductor die 200 prior to the operations of block 401. In other cases, stop pads may be deposited in predetermined, selected areas where a laser tool forms vias 700 at block 403.

At block 404, vias 700 may be filled with a thermally conductive material (e.g., an Sn/Ag solder alloy, copper, etc.), thus resulting in filled vias 205 shown in FIG. 9. At block 405, a layer of adhesive material 206 (e.g., a viscous polymer, etc.) may be used to bond or otherwise couple heat spreader 207 to encapsulant 203, as shown in FIG. 10. Filled vias 205 may be metallurgically joined to spreader 207 using, for example, solder. In an alternative embodiment, the same thermally conductive material filling vias 205 may also be used to form heat spreader 207 over the surface of encapsulant 203 and/or over layer of adhesive material 206 in one (or more) operation(s). Thereafter, at block 406, a sphere attach process may create solder balls or spheres 202, and a reflow process may act upon the thermally conductive material within filled vias 205, as shown in FIG. 11, so that the thermally conductive material may properly join heat spreader 207. For instance, the entire assembly may be subjected to controlled heat, which melts the thermally conductive material within filled vias 205. In some cases, a singulation process may then separate individual components fabricated and packaged over the same semiconductor substrate 201 (e.g., when elements are received and/or processed in an array or strip format).

It should be understood that the various operations described herein, particularly in connection with FIGS. 4-11, may be controlled at least in part by software executed by processing circuitry within one or more semiconductor manufacturing tools or the like. The order in which each operation of a given method is performed may be changed, and various elements of the systems illustrated herein may be added, reordered, combined, omitted, modified, etc. It is intended that the invention(s) described herein embrace all such modifications and changes and, accordingly, the above description should be regarded in an illustrative rather than a restrictive sense.

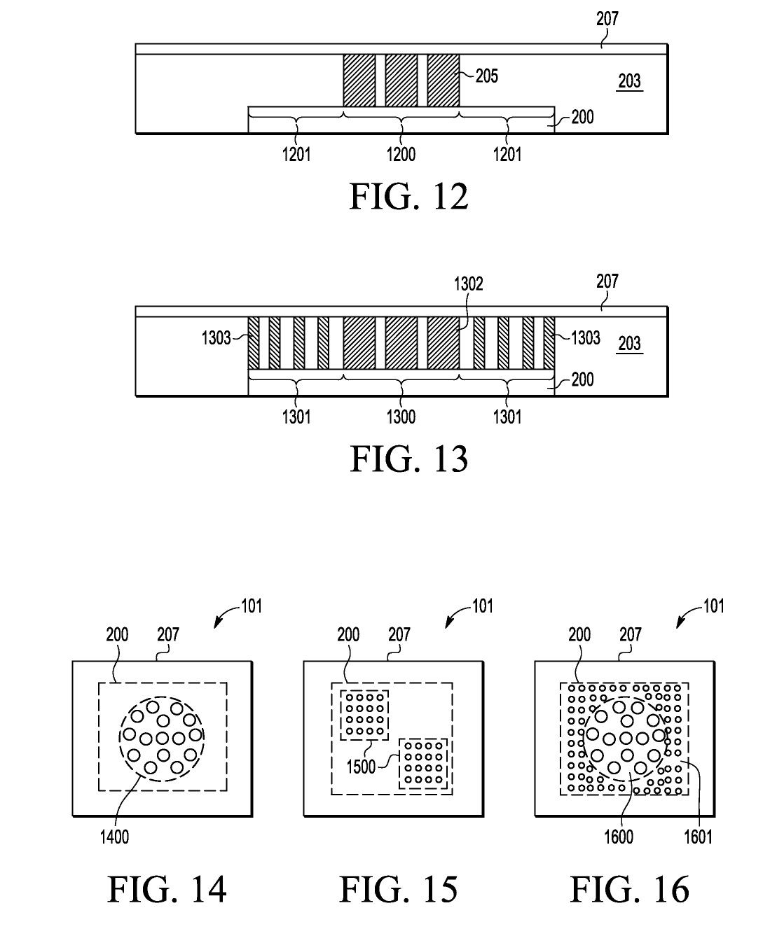

FIG. 12 is a cross-sectional diagram illustrating a design of a thermally enhanced electronic component package with through mold vias according to some embodiments. It should be noted that other elements described above (e.g., adhesive layer(s), stop pad(s), wirebonds 204, etc.) are absent from FIG. 12 for simplicity of explanation. As illustrated, semiconductor die 200 is coupled to heat spreader 207 through filled vias 205 drilled in encapsulant 203. As illustrated, filled vias 205 couple top surface region 1200 of die 200 to heat spreader 207 to the exclusion of top surface region(s) 1201. In some cases, area 1200 may correspond to a region of an integrated circuit fabricated on die 200 that is designed or expected to reach higher operating temperatures than region(s) 1201. For example, in cases where semiconductor die 200 includes a microprocessor, region 1200 may correspond to a processing core. Additionally or alternatively, region(s) 1201 may be such that they are not amenable to laser drilling, or they may have electrical or electro-mechanical characteristics that would make them sensitive to the presence of filled vias 205; hence filled vias 205 are not fabricated over them. Although only one region 1200 is shown coupled to filled vias 205 in FIG. 12, it should be understood that, in other examples, two or more thermally coupled areas such as region 1200 may be interspersed by other areas such as region(s) 1201.

FIG. 13 is a cross-sectional diagram illustrating a design of another thermally enhanced electronic component package with through mold vias according to some embodiments. Similarly as above, other elements previously described are absent from FIG. 13 for simplicity of explanation. As shown, a first set of filled vias 1302 is provided in encapsulant 203 to couple heat spreader 207 to a first region 1300 of the top surface of semiconductor die 200. A second set of filled vias 1303 couples heat spreader 207 to a second region 1301 of the top surface of heat semiconductor die 200. As illustrated, the number of vias in the first and second sets of filled vias 1302 and 1303, respectively, may be different from each other. Additionally or alternatively, the aggregate cross-sectional area of the first and second sets of filled vias 1302 and 1303 may be different from each other. Additionally or alternatively, the size (e.g., diameter) of vias in the first and second sets of filled vias 1302 and 1303 may be different from each other. Additionally or alternatively, the spacing between vias in the first and second sets of filled vias 1302 and 1303 may be different from each other. In various embodiments, these differences between the first and second sets of filled vias may be provided per unit area of the underlying component (e.g., the top surface of semiconductor die 200) and/or of the outer surface of encapsulation 203. Moreover, the number, size, and spacing of vias in a given set of filled vias may be designed to allow a corresponding portion of the integrated circuit within die 200 to dissipate heat produced during the circuit's operation. Accordingly, the presence, type and/or density of filled vias across the surface of die 200 may vary according to the thermal requirements of different portions of die 200.

FIGS. 14-16 are top view diagrams illustrating designs of thermally enhanced electronic component packages with through mold vias according to some embodiments. Particularly, FIG. 14 shows a set of vias in a first region 1400 corresponding to a predetermined area of semiconductor die 200—in this case, a central region of circular shape—connecting die 200 to heat spreader 207 and having a first diameter and effective cross sectional area. FIG. 15 shows two discreet sets of filled vias in regions 1500 of corresponding to predetermined areas of die 200—in this case, two regions of square shape separated by areas without vias-connecting die 200 to heat spreader 207 and each region having filled vias of same diameter and same effective cross sectional area. FIG. 16 shows different sets of filled vias over regions 1600 and 1601, respectively, each set of filled vias having different diameters and/or effective cross sectional areas.

Still referring to FIGS. 14-16, it should be noted that, in various embodiments, through mold vias may occupy regions (e.g., regions 1400, 1500, 1600, and 1601) having any geometric shape. A suitable geometric shape of one or more via filled-regions, number of vias in each region, location of vias, diameter of vias, aggregate cross-section area of vias, etc. may be chosen for instance, depending upon the design of the integrated circuit or other device fabricated in the die 200, and/or upon the circuit's temperature distribution when in operation. In a typical component, the size of die 200 may be, for example, 8 mm×8 mm, and the extent of the encapsulant 203 (not shown in FIGS. 14-16) may be, for example, 28 mm×28 mm. In other embodiments, however, die 200 and encapsulant 203 may have any suitable dimensions. In some implementations, the surface of heat spreader 207 may be co-extensive with the surface of encapsulant 203, as shown in FIGS. 12 and 13. In other implementations, the surface of heat spreader 207 may be co-extensive with, or greater than, the surface of die 200. For a given though mold via design, a computer-based simulation may be performed so that a user may be able to change one or more of the aforementioned variables in order to achieve a desirable heat dissipation result for a specific component or a particular area thereof.

In an illustrative, non-limiting embodiment, a method may include forming one or more vias through an encapsulant with a laser, each of the one or more vias having one end proximal a top surface of an electronic component covered by the encapsulant and another end proximal an outer surface of the encapsulant. The method may also include inserting a thermally conductive material into the one or more vias, providing a heat spreader over the outer surface of the encapsulant, the heat spreader thermally coupled to the thermally conductive material, and reflowing the thermally conductive material.

In some embodiments, the electronic component may include an integrated circuit, the encapsulant may include an epoxy material, the thermally conductive material may include solder, and the heat spreader may include a copper layer. The heat spreader may be metallurgically coupled to the thermally conductive material and adhesively coupled to the encapsulant using an adhesive layer. The thermally conductive material inserted into the one or more vias may be thermally coupled to the top surface of the electronic component through one or more laser stop pads, and each of the one or more laser stop pads may include a metal pad. Portions of the top surface of the electronic component lacking any of the one or more vias may also lack a layer of thermal interface material. Moreover, the heat spreader may have a thickness greater than 0.1 mm and smaller than 0.5 mm.

In some cases, the one or more vias may be formed upon a region of the encapsulant above a first portion of the top surface of the electronic component to the exclusion of another region of the encapsulant above a second portion of the top surface of the electronic component, the first portion of the top surface of the electronic component having a different geometric shape than the second portion of the top surface of the electronic component. Additionally or alternatively, the one or more vias may include a first set of vias above a first portion of the top surface of the electronic component and a second set of vias above a second portion of the top surface of the electronic component, wherein the first set of vias has a larger number of vias per unit area than the second set of vias. Additionally or alternatively, the one or more vias may include a first set of vias above a first portion of the top surface of the electronic component and a second set of vias above a second portion of the top surface of the electronic component, wherein the first set of vias has a larger effective cross sectional area per unit area than the second set of vias. In some cases, the first portion of the top surface of the electronic component may be configured to attain a higher temperature than the second portion of the top surface of the electronic component during the electronic component's operation.

In another illustrative, non-limiting embodiment, an electronic component package may include an electronic component at least partially covered by an encapsulant, the encapsulant having one or more laser-drilled vias filled with a reflown thermally conductive material, each of the laser-drilled, filled vias thermally coupled to the surface of the electronic component through a laser stop material, the thermally conductive material thermally coupled to a heat spreader at an outer surface of the encapsulant. For example, the heat spreader may have a surface area at least co-extensive with an area of the surface of the electronic component.

In some embodiments, the one or more laser-drilled, filled vias may be formed upon a region of the encapsulant above a first portion of the top surface of the electronic component to the exclusion of another region of the encapsulant above a second portion of the top surface of the electronic component. Additionally or alternatively, the first set of vias may have a larger number of vias per unit area than the second set of vias. Additionally or alternatively, the first set of vias may have a larger effective cross sectional area per unit area than the second set of vias. Moreover, the first portion of the top surface of the electronic component may reach a higher temperature than the second portion of the top surface of the electronic component during the electronic component's operation.

In an illustrative, non-limiting embodiment, a method may include forming one or more vias through an encapsulant, each of the one or more vias having one end proximal a top surface of an electronic component covered by the encapsulant and another end proximal an outer surface of the encapsulant, the top surface of the electronic component lacking a plating layer of thermal interface material. The method may also include inserting a thermally conductive material into the one or more vias and providing a heat spreader over the outer surface of the encapsulant, the heat spreader thermally coupled to the thermally conductive material, the heat spreader having a thickness greater than 0.1 mm. Additionally or alternatively, heat spreader may have a thickness smaller than 0.5 mm.

For example, the electronic component may include an integrated circuit, the encapsulant may include an epoxy material, the thermally conductive material may include solder or copper, and the heat spreader may include a copper layer. Also, the heat spreader may be metallurgically coupled to the thermally conductive material and adhesively coupled to the encapsulant using an adhesive layer. In some cases, creating the one or more vias may include drilling one or more regions of the encapsulant with a laser. For instance, the thermally conductive material inserted into the one or more vias may be thermally coupled to the top surface of the electronic component through one or more laser stop pads, and each of the one or more laser stop pads may include a metal pad.

In some embodiments, the one or more vias may be formed upon a region of the encapsulant above a first portion of the top surface of the electronic component to the exclusion of another region of the encapsulant above a second portion of the top surface of the electronic component, the first portion of the top surface of the electronic component having a different geometric shape than the second portion of the top surface of the electronic component. Additionally or alternatively, the one or more vias may include a first set of vias above a first portion of the top surface of the electronic component and a second set of vias above a second portion of the top surface of the electronic component, where the first set of vias has a larger number of vias per unit area than the second set of vias. Additionally or alternatively, the one or more vias may include a first set of vias above a first portion of the top surface of the electronic component and a second set of vias above a second portion of the top surface of the electronic component, where the first set of vias has a larger effective cross sectional area per unit area than the second set of vias. For example, the first portion of the top surface of the electronic component may attain a higher temperature than the second portion of the top surface of the electronic component during the electronic component's operation.

In another illustrative, non-limiting embodiment, an electronic component package may include an electronic component at least partially covered by an encapsulant, the encapsulant having one or more vias filled with a thermally conductive material, the thermally conductive material configured to thermally couple a surface of the electronic component to a heat spreader, the surface of the electronic component lacking a layer of thermal interface material, and the heat spreader having a thickness greater than 0.1 mm.

In some implementations, the one or more vias may be laser-drilled vias, the one or more vias may be coupled to the surface of the electronic component through a laser stop material, and the one or more vias may be metallurgically coupled to the heat spreader. For example, the heat spreader may have a surface area co-extensive with an area of the surface of the electronic component. Alternatively, the heat spreader may have a surface area greater an area of the surface of the electronic component.

In yet another illustrative, non-limiting embodiment, a device may include an electronic component package having an electronic component at least partially enclosed within an encapsulant, the encapsulant having a plurality of filled vias containing a thermally conductive material, the plurality of filled vias coupling a top surface of the electronic component to a heat spreader located at an outer surface of the encapsulant, and the heat spreader having a thickness between 0.1 mm and 0.5 mm.

In some cases, the plurality of filled vias may be located in a first region of the encapsulant above a first portion of the top surface of the electronic component and absent from a second region of the encapsulant above a second portion of the top surface of the electronic component, and the first portion of the surface of the circuit may reach a higher operating temperature than the second portion of the surface of the circuit. Additionally or alternatively, the plurality of filled vias may include a first set of filled vias thermally coupled to a first portion of the top surface of the electronic component and a second set of filled vias thermally coupled to a second portion of the top surface of the electronic component, the first set of filled vias may have more vias than the second set of filled vias per unit area, and the first portion of the top surface of the electronic component may reach a higher operating temperature than the second portion of the top surface of the electronic component. Additionally or alternatively, the plurality of filled vias may include a first set of filled vias coupled to a first portion of the top surface of the electronic component and a second set of filled vias coupled to a second portion of the top surface of the electronic component, the first set of filled vias may have a larger aggregate cross sectional area than the second set of filled vias per unit area, and the first portion of the top surface of the electronic component may reach a higher operating temperature than the second portion of the top surface of the electronic component.

In an illustrative, non-limiting embodiment, a method may include creating one or more vias through a mold compound, the one or more vias coupling a top surface of a semiconductor material covered by the mold compound to an outer surface of the mold compound, inserting a thermally conductive material into the one or more vias, and placing a heat spreader over the outer surface of the mold compound, the heat spreader coupled to the thermally conductive material. For example, the semiconductor material may include a die having an integrated circuit fabricated thereon, the mold compound may include an epoxy material, the thermally conductive material may include solder or copper, and the heat spreader may include a copper layer.

In some implementations, the heat spreader may be metallurgically coupled to the thermally conductive material and coupled to the mold compound using an adhesive layer. The method may also include creating the one or more vias by drilling one or more regions of the mold compound with a laser. In those cases, the one or more vias may be coupled to the top surface of the semiconductor material through one or more laser stop pads, and each of the one or more laser stop pads may be a metal pad.

In some embodiments, the one or more vias may be created upon a region of the mold compound above a first portion of the top surface of the semiconductor material to the exclusion of another region of the mold compound above a second portion of the top surface of the semiconductor material, and the first portion of the top surface of the semiconductor material may attain a higher temperature than the second portion of the top surface of the semiconductor material during operation of an integrated circuit fabricated on the semiconductor material. Additionally or alternatively, the one or more vias may include a first set of vias above a first portion of the top surface of the semiconductor material and a second set of vias above a second portion of the top surface of the semiconductor material, the first set of vias may have a larger number of vias than the second set of vias, and the first portion of the top surface of the semiconductor material may attain a higher temperature than the second portion of the top surface of the semiconductor material during operation of an integrated circuit fabricated on the semiconductor material. Additionally or alternatively, the one or more vias may include a first set of vias above a first portion of the top surface of the semiconductor material and a second set of vias above a second portion of the top surface of the semiconductor material, the first set of vias may have a first effective cross sectional area larger than a second effective cross sectional area of the second set of vias, and the first portion of the top surface of the semiconductor material may attain a higher temperature than the second portion of the top surface of the semiconductor material during operation of an integrated circuit fabricated on the semiconductor material.

In another illustrative, non-limiting embodiment, a electronic component may include an integrated circuit at least partially covered by a mold compound, the mold compound having one or more vias filled with a thermally conductive material, the thermally conductive material coupling a surface of the integrated circuit to a heat spreader located on a surface of the mold compound. In some cases, the one or more vias may be laser-drilled vias, the one or more vias may be coupled to the surface of the integrated circuit through a laser stop material, and the one or more vias may be metallurgically coupled to the heat spreader. Also, the heat spreader may have a surface area substantially equal to an area of the surface of the integrated circuit. Alternatively, the heat spreader may have a surface area greater than an area of the surface of the integrated circuit.

In some embodiments, the one or more vias may include a first set of vias coupled to a first portion of the surface of the integrated circuit and a second set of vias coupled to a second portion of the surface of the integrated circuit, the first set of vias may include more vias per unit area than the second set of vias, and the first portion of the surface of the integrated circuit may attain a higher temperature than the second portion of the surface of the integrated circuit during operation of the integrated circuit. Additionally or alternatively, the one or more vias may include a first set of vias coupled to a first portion of the surface of the integrated circuit and a second set of vias coupled to a second portion of the surface of the integrated circuit, the first set of vias may have a larger number of vias than the second set of vias, and the first portion of the surface of the integrated circuit may attain a higher temperature than the second portion of the surface of the integrated circuit during operation of the integrated circuit. Additionally or alternatively, the one or more vias may include a first set of vias coupled to a first portion of the surface of the integrated circuit and a second set of vias coupled to a second portion of the surface of the integrated circuit, the first set of vias may have a first effective cross sectional area larger than a second effective cross sectional area of the second set of vias, and the first portion of the surface of the integrated circuit may attain a higher temperature than the second portion of the surface of the integrated circuit during operation of the integrated circuit.

In yet another illustrative, non-limiting embodiment, a device may include a an electronic component having a circuit at least partially enclosed within a package, the package having a plurality of vias filled with a thermally conductive material, the plurality of vias coupling a surface of the circuit to a heat spreader located at or near a surface of the package. In some implementations, the plurality of vias may be coupled to the surface of the circuit through a stop material, and the plurality of vias may be metallurgically coupled to the heat spreader.

In some embodiments, the plurality of vias may be located in a first region of the package above a first portion of the surface of the circuit and absent from a second region of the package above a second portion of the surface of the circuit, and the first portion of the surface of the circuit may reach a higher operating temperature than the second portion of the surface of the circuit. Additionally or alternatively, the plurality of vias may include a first set of vias coupled to a first portion of the surface of the circuit and a second set of vias coupled to a second portion of the surface of the circuit, the first set of vias may have more vias than the second set of vias, and the first portion of the surface of the circuit may reach a higher operating temperature than the second portion of the surface of the circuit. Additionally or alternatively, the plurality of vias may include a first set of vias coupled to a first portion of the surface of the circuit and a second set of vias coupled to a second portion of the surface of the circuit, the first set of vias may have a first aggregate cross sectional area larger than a second aggregate cross sectional area of the second set of vias, and the first portion of the surface of the circuit may reach a higher operating temperature than the second portion of the surface of the circuit.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The term “coupled” is defined as connected, although not necessarily directly, and not necessarily mechanically. The term “thermally coupled” means coupled to promote a heat exchange process. The term “adhesively coupled” means coupled via an adhesive and/or adhesive process. The term “metallurgically coupled” means coupled via a metallurgical process. The terms “proximal” and “proximate” are defined as situated or positioned close or next to. For example, if a via has an end proximal a surface, when the via is filled with a given material, the filling material may then become at least thermally coupled to the surface. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. A method, comprising:
forming one or more vias through an encapsulant with a laser, each of the one or more vias having one end proximal a top surface of an electronic component covered by the encapsulant and another end proximal an outer surface of the encapsulant;
inserting a thermally conductive material into the one or more vias;
providing a heat spreader over the outer surface of the encapsulant, the heat spreader thermally coupled to the thermally conductive material; and
reflowing the thermally conductive material.

2. The method of claim 1, wherein the electronic component includes an integrated circuit, wherein the encapsulant includes an epoxy material, wherein the thermally conductive material includes solder, and wherein the heat spreader includes a copper layer.

3. The method of claim 1, wherein the heat spreader is metallurgically coupled to the thermally conductive material and adhesively coupled to the encapsulant using an adhesive layer.

4. The method of claim 1, wherein the thermally conductive material is thermally coupled to the top surface of the electronic component through one or more laser stop pads, and wherein each of the one or more laser stop pads includes a metal pad.

5. The method of claim 1, wherein portions of the top surface of the electronic component lacking any of the one or more vias also lack a layer of thermal interface material.

6. The method of claim 1, wherein the heat spreader has a thickness greater than 0.1 mm and smaller than 0.5 mm.

7. The method of claim 1, wherein the one or more vias are formed upon a region of the encapsulant above a first portion of the top surface of the electronic component to the exclusion of another region of the encapsulant above a second portion of the top surface of the electronic component, the first portion of the top surface of the electronic component having a different geometric shape than the second portion of the top surface of the electronic component.

8. The method of claim 7, wherein the first portion of the top surface of the electronic component is configured to attain a higher temperature than the second portion of the top surface of the electronic component during the electronic component's operation.

9. The method of claim 1, wherein the one or more vias include a first set of vias above a first portion of the top surface of the electronic component and a second set of vias above a second portion of the top surface of the electronic component, wherein the first set of vias has a larger number of vias per unit area than the second set of vias.

10. The method of claim 9, wherein the first portion of the top surface of the electronic component is configured to attain a higher temperature than the second portion of the top surface of the electronic component during the electronic component's operation.

11. The method of claim 1, wherein the one or more vias include a first set of vias above a first portion of the top surface of the electronic component and a second set of vias above a second portion of the top surface of the electronic component, wherein the first set of vias has a larger effective cross sectional area per unit area than the second set of vias.

12. The method of claim 11, wherein the first portion of the top surface of the electronic component is configured to attain a higher temperature than the second portion of the top surface of the electronic component during the electronic component's operation.

13. An electronic component package, comprising:
an electronic component at least partially covered by an encapsulant, the encapsulant having one or more laser-drilled vias filled with a reflown thermally conductive material, each of the laser-drilled, filled vias thermally coupled to a surface of the electronic component through a laser stop material, the thermally conductive material thermally coupled to a heat spreader at an outer surface of the encapsulant.

14. The electronic component package of claim 13, wherein the heat spreader has a surface area at least co-extensive with an area of the surface of the electronic component.

15. The electronic component package of claim 13, wherein the one or more laser-drilled, filled vias are formed upon a region of the encapsulant above a first portion of the top surface of the electronic component to the exclusion of another region of the encapsulant above a second portion of the top surface of the electronic component.

16. The electronic component package of claim 15, wherein the first portion of the top surface of the electronic component is configured to reach a higher temperature than the second portion of the top surface of the electronic component during the electronic component's operation.

17. The electronic component package of claim 13, wherein the one or more laser-drilled, filled vias include a first set of vias above a first portion of the top surface of the electronic component and a second set of vias above a second portion of the top surface of the electronic component, wherein the first set of vias has a larger number of vias per unit area than the second set of vias.

18. The electronic component package of claim 17, wherein the first portion of the top surface of the electronic component is configured to reach a higher temperature than the second portion of the top surface of the electronic component during the electronic component's operation.

19. The electronic component package of claim 13, wherein the one or more laser-drilled, filled vias include a first set of vias above a first portion of the top surface of the electronic component and a second set of vias above a second portion of the top surface of the electronic component, wherein the first set of vias has a larger effective cross sectional area per unit area than the second set of vias.

20. The electronic component package of claim 19, wherein the first portion of the top surface of the electronic component is configured to reach a higher temperature than the second portion of the top surface of the electronic component during the electronic component's operation.
